(19) United States
(12) Patent Application Publication
(10) Pub. No.: US 2004/0070454 A1
(43) Pub. Date: Apr. 15, 2004

(54) Continuous bias circuit and method for an amplifier

(75) Inventors: Gregory N. Henderson, Sudbury, MA (US); Christopher C. Souchuns, Ashland, MA (US); Li Liu, Littleton, MA (US); Ping Li, Dunstable, MA (US); On San Andy Tang, Merrimack, NH (US); Ashley A. Imhoff, Boxford, MA (US)

Correspondence Address: BEVER HOFFMAN & HARMS, LLP, TRI-VALLEY OFFICE, 1432 CONCANNON BLVD., BLDG. G, LIVERMORE, CA, 94550, US

(73) Assignee: TriQuint Semiconductor, Inc.

(21) Appl. No.: 10/607,959

(22) Filed: Jun. 27, 2003

Related U.S. Application Data
(60) Provisional application No. 60/418,816, filed on Oct. 15, 2002.

(51) Int. Cl. H03G 3/10

(52) U.S. Cl. 330/285

(57) ABSTRACT

An amplifier and a bias circuit are disclosed. The bias circuit receives an analog voltage signal that reflects a desired output power level of the amplifier. The bias circuit causes the amplifier to draw a quiescent current, from a fixed-level DC voltage supply, that varies proportionally with the analog voltage signal. In this way, the current consumption of the amplifier is optimized for the desired output power level, while maintaining a desired, high degree of linearity. The amplifier and bias circuit may be in a wireless communications device that includes a baseband processor. The baseband processor generates the analog voltage signal, and a data signal that is converted to a RF signal. The RF signal is amplified by a preamplifier to a power level determined by the analog voltage signal. The RF signal is output to the amplifier for further amplification, and subsequently is broadcast through an antenna.

### CROSS-REFERENCE TO RELATED APPLICATION

This application claims priority to U.S. Provisional Patent Application Serial No. 60/418,816, which is incorporated herein by reference in its entirety.

### BACKGROUND OF THE INVENTION

1. Technical Field

The present disclosure relates to amplifiers, and amongst other things, to a bias circuit and method for biasing an amplifier.

2. Discussion of the Related Art

Radio frequency (RF) amplifiers are often used in portable, battery operated devices, such as cellular telephones. Performance of such an amplifier is largely judged by the amplifier's linearity and power efficiency. Linearity requires proportional amplification with low distortion over a wide dynamic range. Power efficiency requires low power consumption over the dynamic range. Typically, linearity is achieved at a cost to power efficiency, or vice versa.

For instance, in order to provide linearity over a wide dynamic range, it is conventional to bias the amplifier to operate most efficiently at a single output power level in the dynamic range. Typically, the selected single output power level is the level at which, statistically, the amplifier most commonly operates. This is effective for providing linearity over the dynamic range, but only provides power efficiency at the single output power level.

An alternative approach to improve power efficiency, while maintaining linearity, is to provide multiple amplifier stages and to combine their outputs. Such an approach allows a designer to separately optimize the power efficiency of each of the multiple amplifier stages. While this approach constitutes an improvement over biasing for a single output power level, efficiency is still improved at only a small number of the possible output power levels.

Therefore, a need exists to improve the power efficiency of an amplifier while still maintaining linearity over a wide dynamic range of operation.

### SUMMARY OF THE DISCLOSURE

The present invention includes a method and a circuit for controlling the output power level and current consumption of an amplifier, while maintaining a desired, high degree of linearity.

An exemplary embodiment in accordance with the present invention includes a bias circuit coupled to an amplifier. The bias circuit receives an analog, i.e., continuously-varying voltage signal. The voltage signal is reflective of a desired output power level of a signal to be output by the amplifier. The bias circuit generates a continuously-varying current that is proportional to the analog voltage signal, and causes the amplifier to draw a similarly proportional quiescent current from a fixed-voltage level DC voltage source. Accordingly, the current consumption of the amplifier is optimized for the desired output power level.

In one embodiment, the amplifier and bias circuit are part of a wireless communications device, such as a cellular phone or a personal digital assistant device. A baseband processor of the wireless communications device generates a data signal, which is converted to a RF signal. The baseband processor also generates the analog voltage signal. The baseband processor is coupled to the bias circuit, and provides the analog voltage signal to the bias circuit. The RF signal is amplified by a preamplifier to a power level determined by the analog voltage signal. The preamplifier provides the RF signal to the amplifier for further amplification to the desired output power level. The RF signal subsequently is broadcast through an antenna of the wireless communications device.

These and other aspects of the present invention will become more, apparent through consideration of the accompanying drawings and the following detailed description of the exemplary embodiments.

### BRIEF DESCRIPTION OF THE DRAWINGS

FIG. 1 is a simplified block diagram of an embodiment of a radio frequency transmission circuit, in accordance with the present invention;

FIG. 2 is a simplified block diagram of another embodiment of a radio frequency transmission circuit, in accordance with the present invention;

FIG. 3 is a simplified block diagram of an amplifier bias circuit, in accordance with the present invention;

FIG. 4 is a schematic diagram of an embodiment of the amplifier bias circuit of FIG. 3, in accordance with the present invention;

FIG. 5 is a graph of an analog control voltage input to the amplifier bias circuit versus the output power of the amplifier of FIG. 4;

FIG. 6 is a graph an amplifier quiescent current verses the analog control voltage for the amplifier of FIG. 4;

FIG. 7 is a graph of linearity versus the output power of the amplifier;

FIG. 8 is a graph of current consumption versus output power for the amplifier; and

FIG. 9 is a schematic diagram of another embodiment of an amplifier bias circuit, in accordance with the present invention.

In the present disclosure, like objects which appear in more than one figure are typically provided with like reference numerals.

### DETAILED DESCRIPTION

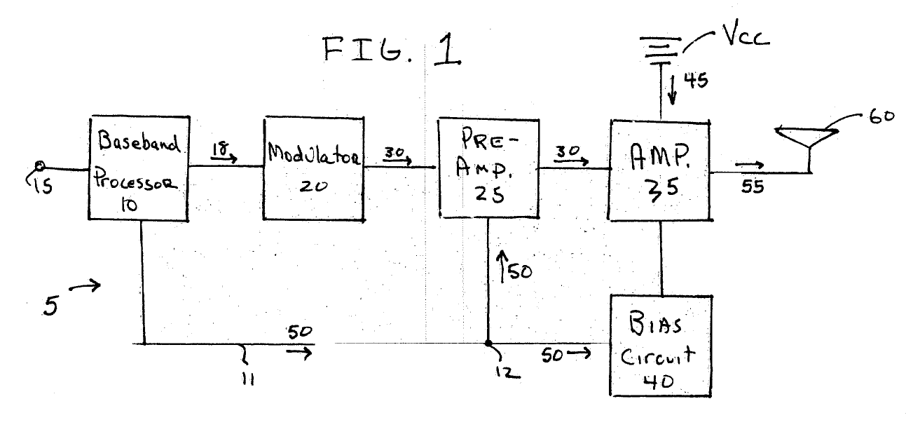

FIG. 1 is a simplified block diagram of an embodiment of a radio frequency transmission circuit 5 in accordance with the present invention.

As an example, radio frequency transmission circuit 5 may be in a battery-operated wireless communications device, e.g., a cellular phone, that transmits and receives RF signals. Radio frequency transmission circuit 5 may operate according to any number of communication standards, including, but not limited to, the CDMA, WCDMA, GSM, or AMPS standards.

Radio frequency transmission circuit 5 includes a baseband processor 10 that receives data, e.g., voice and/or packet data, at input 15. Based on this data input, baseband processor 10 outputs an encoded data signal 18 to a modulator 20. Modulator 20 modulates the data signal 18 to produce a RF signal 30. The RF signal 30 is provided to a preamplifier 25, which amplifies the RF signal 30 and provides it to amplifier 35. Amplifier 35 further amplifies the RF signal 30, and outputs a communication signal 55 that is provided to antenna 60. Antenna 60 broadcasts communication signal 55.

Baseband processor 10 also outputs an analog, i.e., continuously varying, voltage signal 50 that is provided to preamplifier 25 and bias circuit 40 via line 11 and node 12. Voltage signal 50 has a magnitude calculated by baseband processor 10 to achieve a desired power level in the communication signal 55 that is output by amplifier 35 and radiated via antenna 60.

In a wireless communications embodiment, baseband processor 10 determines the magnitude of voltage signal 50 in real time by decoding an output power instruction that baseband processor 10 receives from an external source, such as a base station in communication with a mobile unit (e.g., a cellular phone) that includes radio frequency transmitter 5. The output power instruction is available in most systems that operate according to the WCDMA, CDMA, Global System for Mobile Communications (GSM), and the Advanced Mobile Phone Service (AMPS) standards.

At preamplifier 25, voltage signal 50 is used to adjust the gain of preamplifier 25 using any of several methods. For instance, voltage signal 50 may be input to a bias circuit that causes the amplifier bias current and gain to vary. The magnitude of voltage signal 50 is selected by baseband processor 10 so that preamplifier 25 will provide amplifier 35 with a RF signal 30 having just the right amount of power for amplifier 35 to further amplify it to produce a communications signal 55 having the appropriate power level for broadcast via antenna 60. Baseband processor 10 accounts for the characteristics of amplifier 35.

Meanwhile, bias circuit 40 also receives voltage signal 50 from baseband processor 10 via line 11. Bias circuit 40 is coupled to amplifier 35, and controls an amount of a quiescent current 45 that amplifier 35 draws from a fixed-level DC voltage source Vcc based on the voltage signal 50 received by bias circuit 40. The quiescent current 45 continuously varies in proportion to the continuously-varying voltage of voltage signal 50. The value of quiescent current 45 is selected so that amplifier 35 will have an optimum current consumption for a selected linearity given the output power level selected by baseband processor 10 for communications signal 55.

For example, in one implementation, as the input power of the RF signal 30 provided by preamplifier 25 to amplifier 35 increases (decreases) due to an increase in the voltage of the voltage signal 50 provided to preamplifier 25 by baseband processor 10, which is the means by which baseband processor 10 controls the output power of communication signal 55, bias circuit 40 proportionally increases (decreases) the quiescent current 45 provided to amplifier 35 from a fixed voltage source Vcc, thereby obtaining the optimum current consumption at a desired linearity (e.g., Adjacent Channel Power Ratio (ACPR) of −48 dBc or better) for the selected output power level. The bias current sets the linearity. Increasing the bias current provides more linearity, and vice versa.

Bias circuit 40 may be temperature compensated so that the value of quiescent current 45 will not appreciably vary with temperature.

Amplifier 35 may include a single amplifier stage, or two or more amplifier stages. In the case of a multi-stage amplifier, a single bias circuit 40 can control the quiescent current 45 to one or more of the stages of amplifier 35. Alternatively, a separate bias circuit 40 can be provided for each of the amplifier stages.

In an alternative embodiment, instead of having baseband processor 10 provide the same voltage signal 50 to preamplifier 25 and bias circuit 40, two separate power level signals can be generated by baseband processor 10, with a first signal being provided on a first line to preamplifier 25 and a second signal being provided on a separate line to bias circuit 40.

Referring to FIG. 2, a simplified block diagram of another embodiment of a radio frequency transmission 5 is illustrated. The embodiment of FIG. 2 includes a modulator/preamplifier block 22 that essentially combines the functions of modulator 20 and preamplifier 25 of FIG. 1. In this embodiment, baseband processor 10 only provides analog voltage signal 50 to bias circuit 40. Bias circuit 40, in turn, uses voltage signal 50 to control both the amount of amplification by amplifier 35 and the quiescent current 45 that amplifier 35 draws from Vcc.

In another embodiment, where baseband processor 10 itself can output a modulated RF signal 30, modulator/preamplifier block 22 of FIG. 2 may be omitted.

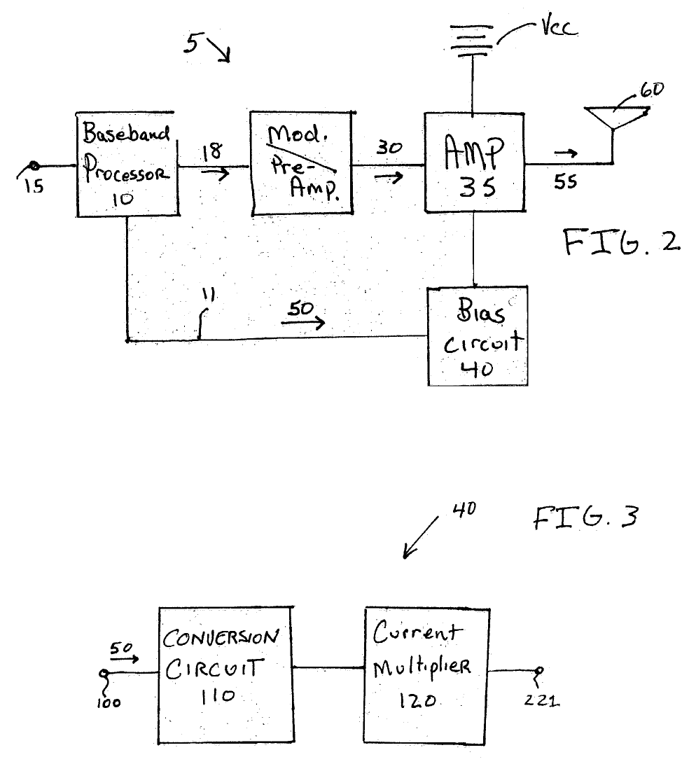

FIG. 3 is a block diagram of an embodiment of a bias circuit 40. An input 100 of bias circuit 40 is coupled to receive analog voltage signal 50 from baseband processor 10 of FIG. 1. Bias circuit 40 of FIG. 3 includes a voltage conversion circuit 110, which receives voltage signal 50 from baseband processor 10 (FIG. 1) via input 100. Conversion circuit 110 shifts, here divides, the voltage of voltage signal 50 to a level suitable for use downstream, and converts voltage signal 50 to a continuously-varying current that is proportional to voltage signal 50. Conversion circuit 110 adjusts the circuit in order to control both the voltage where the current starts to increase and the rate of increase of the quiescent current 45 with the voltage of voltage signal 50. Conversion circuit 110 is coupled to a current multiplier 120 that, in turn, is coupled to amplifier 35 in a manner that allows current multiplier 120 to control the amount of quiescent current 45 that amplifier 35 draws from the fixed-level voltage source Vcc. Current multiplier 120 amplifies/multiplies the current from conversion circuit 110 into amplifier 35.

In one embodiment that may be used, for instance, in a cellular telephone, current multiplier 120 and amplifier circuit 35 of FIG. 1 may be formed together entirely on a single integrated circuit chip, while conversion circuit 110 is formed using discrete components that are separately provided on the same printed circuit board as the single integrated circuit. Such an arrangement allows the user, e.g., a cellular phone manufacturer, to easily vary the components of conversion circuit 110. Accordingly, the manufacturer can easily match a given voltage signal 50 with a bias circuit/amplifier integrated circuit that can be used in several different products. In another embodiment, all of bias circuit 40, including both conversion circuit 110 and current multiplier 120, and all of amplifier 35 may be formed together on a single integrated circuit chip.

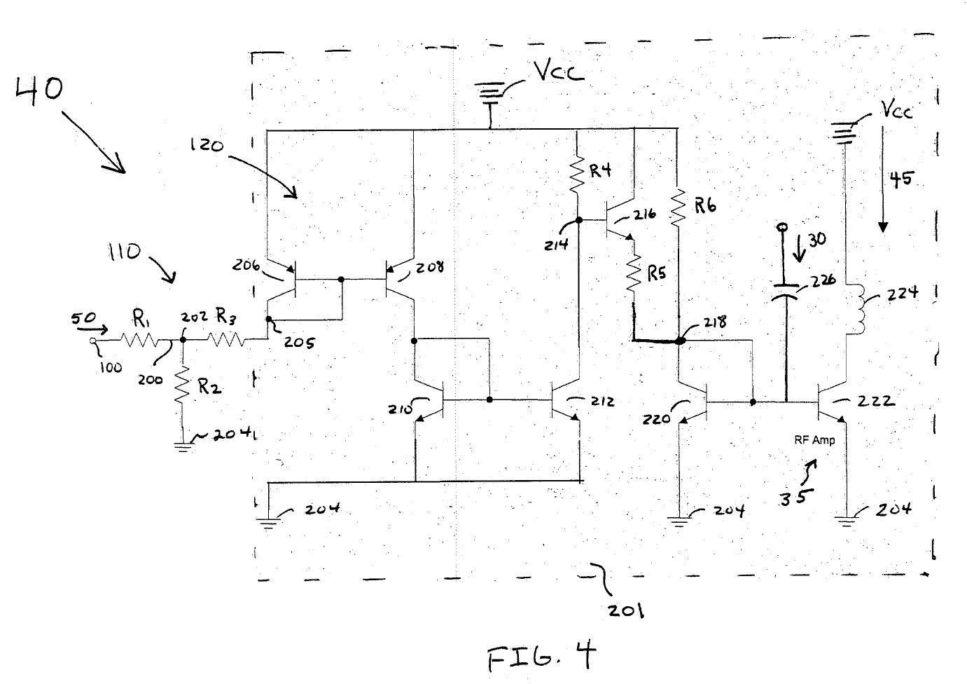

FIG. 4 is a schematic diagram of an embodiment of bias circuit 40 of FIG. 1. Bias circuit 40 includes an input 100 that receives voltage signal 50 from baseband processor 10 (FIG. 1), and provides the voltage signal 50 to conversion circuit 110 (FIG. 3). In this embodiment, conversion circuit 110 is a resistor T-network 200. Resistor T-network 200 includes a resistor R1 coupled between input 100 and a node 202; a resistor R2 coupled between node 202 and ground 204; and a resistor R3 coupled between node 202 and a collector of a PNP transistor 206. Resistor T-network 200 divides voltage signal 50, and converts voltage signal 50 to into a proportional current that flows through the collector of transistor 206.

In the embodiment of FIG. 4, current multiplier 120 includes several transistors and resistors, which will be described below. Current multiplier 120 is coupled to amplifier 35 (FIG. 1). In this embodiment, resistor T-network 200 is formed separately from an integrated circuit 201 that includes both current multiplier 120 and amplifier 35.

In FIG. 4, resistor T-network 200 is coupled via node 205 to the collector and base of a PNP transistor 206 of current multiplier 120, and to the base of another PNP transistor 208. The emitters of transistors 206 and 208 are coupled to DC voltage source Vcc. PNP transistors 206 and 208 form a current mirror. In this embodiment, transistors 206 and 208 have a current mirror ratio of 1:1, but that may vary depending on the application.

PNP transistor 208 has its collector coupled to the collector and base of an NPN transistor 210, and to the base of another NPN transistor 212. The emitters of NPN transistors 210, 212 are coupled to ground 204.

NPN transistors 210, 212 form a current mirror. In this embodiment, transistors 210 and 212 have a current mirror ratio of 1:1, but that may vary depending on the application.

The collector of NPN transistor 212 is coupled to a node 214. Resistor R4 is coupled between Vcc and node 214. The base of NPN transistor 216 also is coupled to node 214. The collector of NPN transistor 216 is coupled to the fixed-level DC voltage source Vcc. A resistor R5 is coupled between the emitter of transistor 216 and a node 218. Transistor 216 is in an emitter follower configuration. Another resistor, R6, is coupled between voltage source Vcc and node 218.

An NPN transistor 220 has its collector and base coupled to node 218 and its emitter coupled to ground 204. A base of an NPN transistor 222 also is coupled to node 218. NPN transistor 222 has its emitter coupled to ground 204, and its collector coupled to the fixed-level DC voltage source Vcc through an inductor 224. In this example, NPN transistor 222 and inductor 224 are part of amplifier 35 of FIG. 1. The emitters of transistors 220, 222 are coupled to ground 204. Hence, bias circuit 45 and amplifier 35 are coupled at node 221 in a current mirror formed by transistor 220 of bias circuit 45 and transistor 222 of amplifier 35.

A RF signal 30 (FIG. 1) that is to be amplified by amplifier 35 is provided to the base of transistor 222 through a coupling capacitor 226.

As mentioned, NPN transistors 220 and 222 of FIG. 4 form a current mirror. In this embodiment, however, transistors 220 and 222 do not have a unity current mirror ratio, but rather have a current mirror ratio set so that much more current passes through transistor 222 than through transistor 220. For instance, transistors 220 and 222 may have a current mirror ratio of between about 1:60 and 1:80. Such a ratio is obtained by varying the size of the emitter junctions of transistors 220 and 222.

In operation, the bias circuit 40 of FIG. 4 receives analog voltage signal 50 from baseband processor 10 at input 100. Resistor T-network 200 of bias circuit 40 divides voltage signal 50, and converts analog voltage signal 50 to a proportional current drawn from voltage source Vcc through the collector of transistor 206. This current is mirrored through the two current mirrors formed by transistors 206, 208 and 210, 212. Accordingly, transistor 212 draws a current from voltage source Vcc through resistor R4 that is proportional to the continuously varying voltage of voltage signal 50. The resulting voltage at node 214 causes transistor 216 to pass a current from Vcc through transistor R5. The current through resistor R5 continuously varies in proportion to the continuously-varying voltage of voltage signal 50. A constant level current also is drawn from voltage source Vcc through transistor R6. The current through transistors R5 and R6 flows through transistor 220 via node 218.

Hence, the current through transistor 220 has two components: (1) a continuously-varying current portion drawn from power supply Vcc through transistor 216 and resistor R5, which is proportional to voltage signal 50; and (2) a constant current portion drawn from power supply Vcc through resistor R6.

As mentioned, transistor 220 forms a current mirror with transistor 222, which is part of amplifier 35 of FIG. 1. However, because the current mirror ratio of transistors 220 and 222 is about 1:60 to 1:80, transistor 222 draws a much larger quiescent current 45 from the fixed-level DC voltage source Vcc through inductor 224. Quiescent current 45 continuously varies in proportion to the continuously-varying voltage signal 50, but also includes a fixed component due to the constant-level current drawn through resistor R6.

Accordingly, with reference to FIGS. 1 and 4, as baseband processor 10 increases voltage signal 50 so that a more powerful communication signal 55, will be output to antenna 60, the quiescent current 45 drawn by transistor 222 of amplifier 35 from the fixed voltage supply Vcc will increase in direct proportion to the continuously varying voltage of voltage signal 50, thereby providing optimal current consumption at a selected linearity for that output power level. On the other hand, as baseband processor 10 decreases voltage signal 50 so that a less powerful communication signal 55 will be output to antenna 60, the quiescent current 45 drawn by transistor 222 of amplifier 35 from Vcc will decrease in proportion to voltage signal 50, thereby providing an optimal current consumption at the selected linearity for that lower output power level. If voltage signal 50 drops below a threshold level, so that the current through transistor R5 of FIG. 4 is below some set minimum, then the fixed level current drawn through resistor R6 that is mirrored through transistor 222 will provide at least a minimum quiescent current 45 through transistor 222 of amplifier 35.

Our method of biasing is different than a conventional method for cellular telephones, which varies the performance of the RF amplifier by varying the amplifier bias voltage in direct response to a voltage signal output by the baseband processor. In the conventional method, the current consumption versus Vcc is not usually a linear function, and operates over a very small range of Vcc. In the present embodiment, by contrast, the amplifier bias voltage is fixed (Vcc), but the quiescent current 45 drawn by the amplifier from the fixed-level DC supply Vcc varies in direct response to the voltage signal 50 from the baseband processor 10. With our design, the quiescent current 45 can be interfaced directly to the voltage range generated by the baseband processor 10, and the magnitude of the quiescent current 45 can be easily adjusted using the resistor network (e.g., resistor T-network 200) of bias circuit 40. As mentioned, in one embodiment, the resistor T-network 200 is formed separately from a single integrated circuit that includes other portions of bias circuit 40 and amplifier 35, which provides flexibility to the user (e.g., a cellular phone manufacturer).

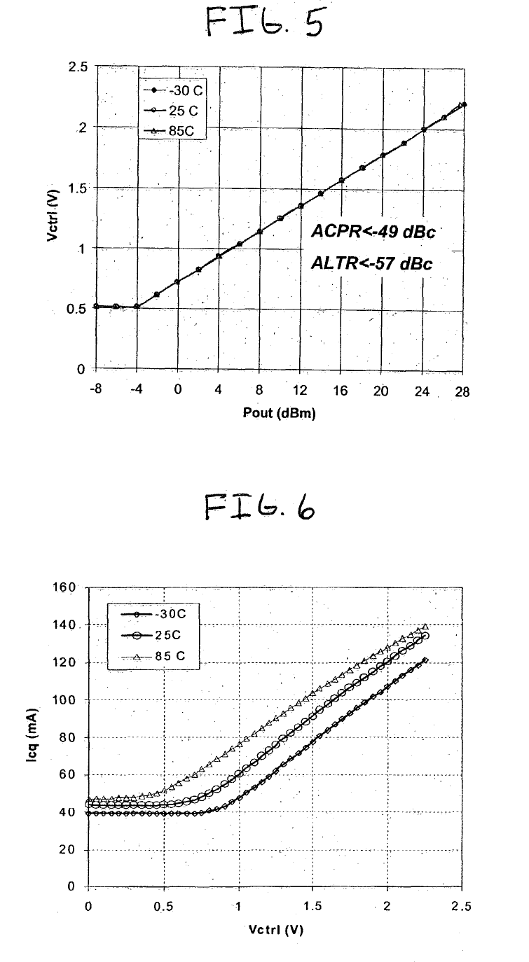

FIGS. 5-8 provide simulation data for the circuit of FIG. 4, which substantiates the superior performance of the methods disclosed herein.

FIG. 5 is a graph of the voltage of the analog voltage signal 50 (denoted Vctrl) versus the output power of an amplifier 35, at three different operating temperatures: −30° C., 25° C., and 85° C. The level of Vctrl is adjusted at each output power to provide a minimum current consumption while providing a desired linearity, which for this example is an ACPR of −48 dBc or better and an ALTR of −57 dBc or better. The curve can be adjusted to provide a desired level of linearity and current consumption for each output power level over the entire dynamic range, by adjusting the resistance values of resistor T-network 200 to increase/decrease the quiescent current 45 for a given voltage of voltage signal 50.

FIG. 6 is a graph of the voltage of voltage signal 50 (denoted Vctrl) provided to bias circuit 40 versus the quiescent current 45 (denoted Icq) provided to amplifier 35, at three temperatures: −30° C., 25° C., and 85° C. The quiescent current is linearly proportional to the voltage of voltage signal 50 over most of the range of voltage signal 50. Note that the quiescent current 45 does not drop to zero as voltage signal 50 approaches zero, but rather only goes to a selected minimum of about 4 mA. As discussed above, this is due to the fixed current drawn through resistor R6 of FIG. 4.

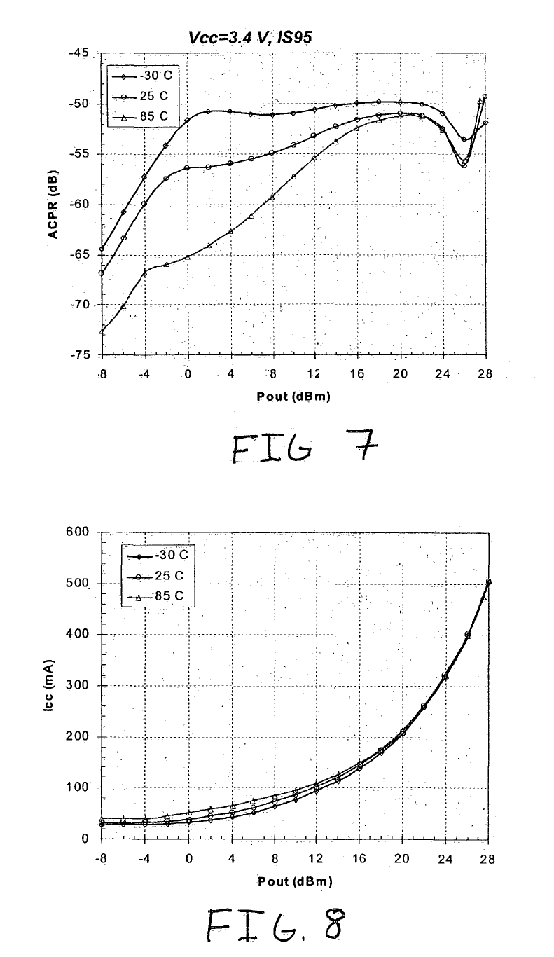

Referring to FIG. 7, a graph of linearity, expressed in terms of ACPR, verses output power for amplifier 35 is provided at three temperatures: −30° C., 25° C., and 85° C. In this example, Vcc of amplifier 35 is 3.4 V. The IS-95 modulation format is used to make the measurements. Here, voltage signal 50 was varied as the input power to the, amplifier was varied in order to keep the ACPR less than, −48 dBc. In this way, no extra quiescent current is used at each output power, and the current consumption is optimized for each output power.

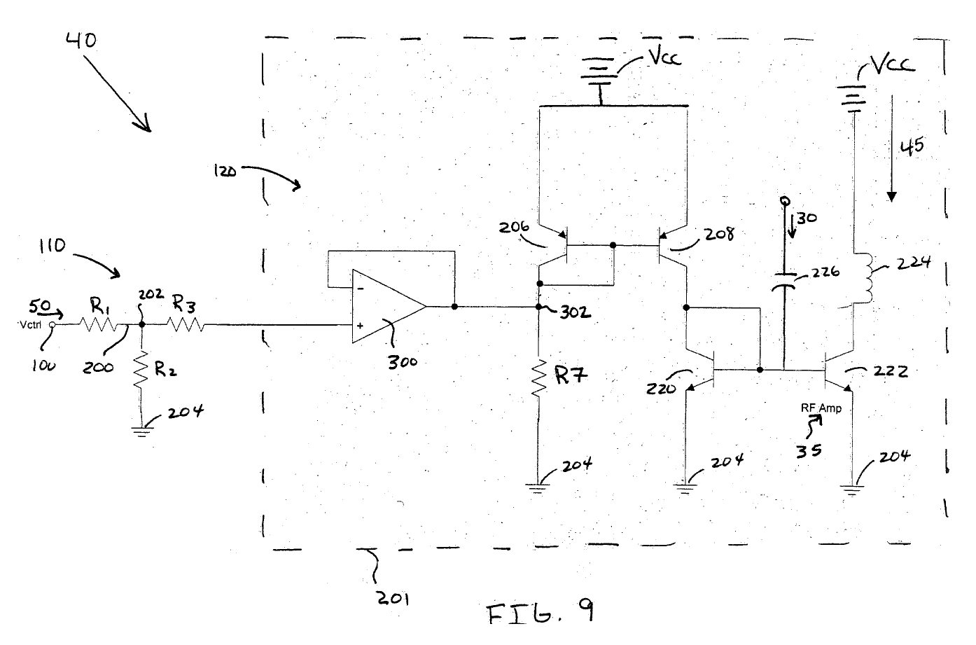

FIG. 8 is a graph of current consumption verses output power for amplifier 35 at three temperatures: −30° C., 25° C., and 85° C. The voltage signal 50 was varied to keep the ACPR less than −48 dBc while minimizing the current consumption. FIG. 8 shows that, while output power is increased, current consumption, and therefore power consumption, is increased Only minimally through the complete dynamic range. In a standard amplifier with a fixed bias, at low power the current consumption would be much higher with excess linearity.

The data of FIGS. 5-8 illustrates that an analog control voltage, such as the voltage signal 50 that is typically output by a baseband processor in cellular phone applications to control the output power level of an amplified communication signal, may be used to proportionally vary the quiescent current provided to an amplifier from a fixed voltage supply Vcc, in a manner that optimizes the current consumption of the amplifier for the specified output power levels, while maintaining a desired, high degree of linearity.

FIG. 9 is another embodiment of bias circuit 40 of FIG. 1. It has similarities to the embodiment of FIG. 4, and hence discussion may be somewhat abbreviated, especially where the same reference numbers are used.

In particular, bias circuit 40 of FIG. 9 includes a conversion circuit 110, which includes a resistor T-network 200. Resistor T-network 200 includes three resistors: resistor R1 between input 100 and node 202, resistor R2 between node 202 and ground 204, and resistor R3 between node 202 and the non-inverting input of an operational amplifier 300. Resistor T-network 200 divides the voltage of voltage signal 50, so that lower rated components may be used within current multiplier 120. As a result, a divided voltage signal is provided to the inverting input of operational amplifier 300 that is proportional to voltage signal 50. The inverting input of operational amplifier 300 is coupled to its output.

Operational amplifier 300 is in an emitter follower configuration, and has unity gain. The output of operational amplifier 300 is provided to a node 302. The voltage drop across resistor R7 between node 302 and ground draws a current from fixed-voltage source Vcc through PNP transistor 206. The current through resistor R7 is varies proportionally with the continuously varying voltage of voltage signal 50 (FIG. 1).

Transistor 206 has its collector coupled to node 302. As in FIG. 4, transistor 206 forms a 1:1 current mirror with PNP transistor 208. Transistor 208 has its collector coupled to the collector and base of NPN transistor 220, and to the base of NPN transistor 222. Transistor 222 is part of amplifier 35 (FIG. 1), and receives the RF signal 30 though coupling capacitor 226. The emitters of transistors 220 and 222 are coupled to ground 204. Transistors 220 and 222 form a current mirror, with a non-unity current mirror ratio (e.g., 1:60-1:80). As in FIG. 4, the bias circuit 45 is coupled to amplifier 35 in a current mirror formed by transistors 220 and 222.

Because of the current mirror configuration of transistors 206 and 208, transistor 220 will draw a continuously-varying current equal to the continuously-varying current through resistor R7. Further, because of the current mirror configuration of transistors 220 and 222, and the non-unity current mirror ratio of transistors 220 and 222, transistor 222 will draw a much large, but still proportionally varying quiescent current 45 from Vcc. Quiescent current 45 varies in proportion to the varying voltage of voltage signal 50.

If desired, a means, such as resistor R6 of FIG. 4, may be provided to ensure that at least a baseline quiescent current 45 is draw from fixed-level, DC voltage supply Vcc by transistor 35.

As used herein, the terms “connected,” “coupled,” or variants thereof, mean any connection or coupling, either direct or indirect, between elements, unless further specified.

The detailed description provided above is merely illustrative, and is not intended to be limiting. While the embodiments, applications and features of the present inventions have been depicted and described, there are many more embodiments, applications and features possible without deviating from the spirit of the inventive concepts described and depicted herein.

What is claimed is:

1. A circuit comprising:
an amplifier coupled to a fixed-level DC voltage source;
a bias circuit coupled to the amplifier, wherein the bias circuit receives a continuously-varying first voltage signal reflective of an output power level of a signal to be output by the amplifier, and based on the first voltage signal causes the amplifier to draw a quiescent current from the voltage source that varies proportionally with the first voltage signal.

2. The circuit of claim 1, wherein the bias circuit comprises a resistor T-network.

3. The circuit of claim 2, wherein the bias circuit comprises a current mirror coupled to the resistor T-network.

4. The circuit of claim 3, wherein the bias circuit is coupled to the amplifier in a current mirror.

5. The circuit of claim 1, wherein the bias circuit is coupled to the amplifier in a current mirror.

6. The circuit of claim 2, wherein a subportion of the bias circuit and the amplifier are together on a single integrated circuit, but the resistor T-network is not on the single integrated circuit.

7. The circuit of claim 3, wherein the bias circuit is coupled to the amplifier in a current mirror.

8. The circuit of claim 3, wherein the current mirror and the amplifier are together on a single integrated circuit, but the resistor T-network is not on the single integrated circuit.

9. The circuit of claim 1, wherein bias circuit comprises a conversion circuit that shifts the voltage of the first voltage signal and converts the first voltage signal to a proportional current, and a current multiplier that multiplies the current into the amplifier as the quiescent current.

10. The circuit of claim 1, wherein the bias circuit generates a current that varies proportionally with the first voltage signal.

11. The circuit of claim 6, wherein the quiescent current includes a constant current portion in addition to a continuously-varying portion.

12. The circuit of claim 1, wherein a transistor of the bias circuit is in a current mirror with a transistor of the amplifier, the current mirror having a non-unity current mirror ratio.

13. A circuit comprising:
an amplifier comprising a first transistor, wherein a collector of the first transistor receives a continuously-varying quiescent current from a fixed-level DC voltage source, and a base of the transistor receives a RF signal to be amplified by the amplifier; and
a bias circuit, wherein the bias circuit comprises a second transistor that is in a current mirror with the first transistor, wherein the quiescent current is a mirror of a current through the first transistor.

14. The circuit of claim 13, wherein the current mirror has a current mirror ratio such that the quiescent current is greater than the current through the second transistor.

15. The circuit of claim 13, wherein the bias circuit receives a continuously-varying voltage signal, and the quiescent current varies proportionally with the voltage signal.

16. The circuit of claim 15, wherein the bias circuit includes a plurality of current mirror circuits.

17. The circuit of claim 13, wherein the bias circuit comprises a resistor T-network.

18. The circuit of claim 17, wherein the bias circuit comprises a current mirror coupled to the resistor T-network.

19. The circuit of claim 17, wherein the amplifier and a portion of the bias circuit, including the second transistor, are together on a single integrated circuit, but the resistor T-network is not on the single integrated circuit.

20. The circuit of claim 13, wherein bias circuit comprises a conversion circuit that shifts the voltage of the first voltage signal and converts the first voltage signal to a proportional current, and the amplifier and a portion of the bias circuit, including the second transistor, are together on a single integrated circuit, but the conversion circuit is not on the single integrated circuit.

21. A wireless communication device comprising:
an amplifier that receives and amplifies a RF signal to be broadcast by the wireless communications device, said amplifier coupled to a fixed-level DC voltage source;
a baseband processor that outputs an analog voltage signal indicative of an output power of the RF signal to be broadcast by the wireless communication device; and
a bias circuit coupled to the amplifier, wherein the bias circuit receives the analog voltage signal and causes the amplifier to draw a quiescent current from the voltage source, and said quiescent current varies proportionally with the analog voltage signal.

22. The wireless communication device of claim 21, wherein the bias circuit includes a resistor T-network that receives the analog voltage signal, and a current mirror coupled to the resistor T-network.

23. The wireless communication device of claim 21, wherein the bias circuit is coupled to the amplifier in a current mirror, the current mirror including a first transistor of the bias circuit and a second transistor of the amplifier, and the RF signal amplified by the amplifier is received by the amplifier at a base of the second transistor.

24. The wireless communication device of claim 21, further comprising a preamplifier that receives the RF signal, amplifies the RF signal, and outputs the RF signal to the amplifier, wherein the preamplifier receives the analog control voltage from the baseband processor, and an amount of the amplification by the preamplifier is controlled by the analog control signal.

25. The wireless communication device of claim 24, further comprising a modulator circuit coupled between the baseband processor and the preamplifier, wherein the modulator circuit receives an encoded data signal from the baseband processor, modulates the data signal to produced the RF signal, and provides the RF signal to the preamplifier.

26. The wireless communication device of claim 21, wherein bias circuit comprises a conversion circuit that shifts the voltage of the first voltage signal and converts the first voltage signal to a proportional current, and the amplifier and a portion of the bias circuit, including the second transistor, are together on a single integrated circuit, but the conversion circuit is not on the single integrated circuit.

27. A wireless communication device comprising:
an amplifier that receives and amplifies a RF signal to be broadcast by the wireless communications device, said amplifier coupled to a fixed-level DC voltage source;
a bias circuit coupled to the amplifier, wherein the bias circuit receives an analog voltage signal, and causes the amplifier to draw a quiescent current that varies proportionally with the analog voltage signal from the voltage source.

28. The wireless communication device of claim 27, wherein the analog voltage signal, reflects a power of the RF signal to be broadcast by the wireless communications device.

29. The wireless communication device of claim 27, wherein the quiescent current includes a constant current portion and an analog current portion that varies proportionally with the analog voltage signal.

30. The wireless communication device of claim 27, wherein the bias circuit is coupled to the amplifier in a current mirror.

31. The wireless communication device of claim 27, further comprising a baseband processor, wherein the baseband processor outputs the analog voltage signal to the bias circuit, and outputs a data signal upon which the RF signal is based.

32. A method of operating an amplifier, comprising:
generating a continuously-varying voltage signal;
providing a first signal to an amplifier, wherein the amplifier amplifies the first signal and outputs the first signal at an output power level reflective of the voltage signal; and
biasing the amplifier with a quiescent current that varies proportionally with the voltage signal.

33. The method of claim 32, wherein the first signal originates from a baseband processor that also outputs the continuously-varying voltage signal, and the first signal is broadcast through an antenna after the amplification.

34. A method of operating a wireless communications device comprising:
generating a data signal and an analog voltage signal in the wireless communications device;
forming a RF signal from said data signal;
amplifying the RF signal in an amplifier of the wireless communications device; and
outputting the amplified RF signal from the amplifier to an antenna of the wireless communications device for broadcasting,
wherein the amplifier is biased with a current from a fixed DC voltage source, said current varies proportionally with the analog voltage signal, and a power level of the RF signal output by the amplifier to the antenna is reflective of the analog voltage signal.

35. The method of claim 34, further comprising providing the, RF signal to a preamplifier, amplifying the RF signal in the preamplifier to a power level based on the analog voltage signal, and outputting the amplifier RF signal from the preamplifier to the amplifier.
